(19) United States
(12) Patent Application Publication
(10) Pub. No.: US 2006/0086519 A1
(43) Pub. Date: Apr. 27, 2006

(54) Casing of an electronic apparatus and manufacturing method for the same

(76) Inventors: Fu-Chi Tsai, Taipei Hsien (TW); Po-Yi Lin, Taipei Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/095,470

(22) Filed: Apr. 1, 2005

Related U.S. Application Data
(62) Division of application No. 10/972,372, filed on Oct. 26, 2004, now abandoned.

(51) Int. Cl. H05K 9/00

(52) U.S. Cl. 174/35 GC

(57) ABSTRACT

A casing of an electronic apparatus has a body and an electromagnetic absorption structure combined with a surface of the body. A manufacturing method for a casing of an electronic apparatus forms a body first, and then disposes an electromagnetic absorption structure on a surface of the body. Another manufacturing method for a casing of an electronic apparatus includes disposing an electromagnetic absorption layer on a surface of a film to form an electromagnetic absorption structure, and then placing the film into a set of molds and using an insert-molding technology to have injection material to form a body combined with the electromagnetic absorption structure to obtain a casing of an electronic apparatus. The casing absorbs electromagnetic waves, and the electromagnetic waves are transformed into heat energy to dissipate and vanish, thereby eliminating the existence of the electromagnetic waves.

### BACKGROUND OF THE INVENTION

1. Field of the Invention

The present invention relates to a casing of an electronic apparatus and a manufacturing method for the same, and more particularly, to a casing of an electronic apparatus that absorbs electromagnetic waves, and a manufacturing method for the same.

2. Background of the Invention

Electronic apparatuses, such as computers, audio-visual equipment, and communications equipment, are fast, popular, and closely linked with our daily life and work. When electronic components inside an electronic apparatus operate, they generate electromagnetic waves, which cause signal interferences with electronic components inside another electronic apparatus, and even have raised health concerns. Taking a cellular phone as an example, because it is easy to bring and use the cellular phone, the cellular phone interferes with other electronic apparatuses easily. Therefore, manufacturers have improved the casing that covers electronic components of an electronic apparatus, so as to lessen the effect of the electromagnetic waves generated from the cellular phone.

A conventional casing of an electronic apparatus includes a body and an electromagnetic shielding structure. The body is a pre-formed body, and the electromagnetic shielding structure is combined with a surface of the body. The electromagnetic shielding structure may be a metal tape adhered on the surface of the body, or a metal layer formed on the surface of the body by spraying, conventional plating, or vacuum plating, etc.

The electromagnetic shielding structure of the above casing of an electronic apparatus is like a shielding wall, and it merely reflects part of electromagnetic waves transmitted toward itself. However, the electromagnetic waves that are reflected still exist, and still easily pass through gaps of the casing or defective areas of the electromagnetic shielding structure. Therefore, this method of dealing with the electromagnetic waves is ineffective; in other words, the effect by using a shielding way to deal with the electromagnetic waves is still limited.

Accordingly, as discussed above, the conventional casing of an electronic apparatus still has some drawbacks that could be improved. The present invention aims to resolve the drawbacks in the prior art.

### SUMMARY OF INVENTION

The primary object of the invention is therefore to specify a casing of an electronic apparatus and a manufacturing method for the same, so that the casing of an electronic apparatus is able to absorb electromagnetic waves, and the electromagnetic waves are transformed into heat energy to dissipate and vanish, thereby eliminating the existence of the electromagnetic waves. Electromagnetic interference is thus lessened, as are health concerns.

Another object of the invention is therefore to specify a casing of an electronic apparatus and a manufacturing method for the same, so that the casing fully absorbs electromagnetic waves, and the structure for absorbing electromagnetic waves is more durable.

According to the invention, the object is achieved via a casing of an electronic apparatus comprising a body and an electromagnetic absorption structure combined with a surface of the body.

The electromagnetic absorption structure is combined with the surface of the body to obtain a casing of an electronic apparatus, such that the casing is able to absorb electromagnetic waves, and the electromagnetic waves are transformed into heat energy to dissipate and vanish, thereby eliminating the existence of the electromagnetic waves.

According to the invention, the object is achieved via a manufacturing method for a casing of an electronic apparatus comprising: (a) forming a body; and (b) disposing an electromagnetic absorption structure on a surface of the body to obtain a casing of an electronic apparatus.

According to the invention, the object is achieved via another manufacturing method for a casing of an electronic apparatus comprising: (a) providing a film; (b) forming an electromagnetic absorption structure: disposing an electromagnetic absorption layer on a surface of the film to form an electromagnetic absorption structure; and (c) injection molding: providing a set of injection molding molds and injection material, placing the electromagnetic absorption structure into the set of injection molding molds, and injecting the injection material into the set of injection molding molds to form a body combined with the electromagnetic absorption structure to obtain a casing of an electronic apparatus.

The electromagnetic absorption layer is disposed on the film first to form an electromagnetic absorption structure. Then the film is placed into the set of injection molding molds and an insert-molding technology is applied, so that the electromagnetic absorption structure completely covers the body to obtain a casing of an electronic apparatus. Therefore, the casing fully absorbs electromagnetic waves. Moreover, the electromagnetic absorption layer is located between the film and the body, so that the structure for absorbing electromagnetic waves is more durable.

To provide a further understanding of the invention, the following detailed description illustrates embodiments and examples of the invention. Examples of the more important features of the invention thus have been summarized rather broadly in order that the detailed description thereof that follows may be better understood, and in order that the contributions to the art may be appreciated. There are, of course, additional features of the invention which will be described hereinafter and which will form the subject of the claims appended hereto.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is a flow chart of a first embodiment of a manufacturing method for a casing of an electronic apparatus of the present invention;

FIG. 2 is a schematic, cross-sectional view of a first embodiment of a casing of an electronic apparatus of the present invention;

FIG. 3 is a flow chart of a second embodiment of a manufacturing method for a casing of an electronic apparatus of the present invention;

FIG. 4 is a schematic, cross-sectional view of a film provided in a second embodiment of a manufacturing method for a casing of an electronic apparatus of the present invention;

FIG. 5 is a schematic, cross-sectional view of a decorative layer and an electromagnetic absorption layer disposed on a film in a second embodiment of a manufacturing method for a casing of an electronic apparatus of the present invention;

FIG. 6 is a schematic, cross-sectional view of an attachment layer attached to an electromagnetic absorption layer on a film in a second embodiment of a manufacturing method for a casing of an electronic apparatus of the present invention;

FIG. 7 is a schematic, cross-sectional view showing when a set of pressing and shaping molds compresses an electromagnetic absorption structure to form it into a three-dimensional shape in a second embodiment of a manufacturing method for a casing of an electronic apparatus of the present invention;

FIG. 8 is a schematic, cross-sectional view showing when a set of punching and shearing machine punches and shears an electromagnetic absorption structure to obtain a predetermined specification thereof in a second embodiment of a manufacturing method for a casing of an electronic apparatus of the present invention;

FIG. 9 is a schematic, cross-sectional view showing when an injection material is injected into a set of injection molding molds to combine with an electromagnetic absorption structure in a second embodiment of a manufacturing method for a casing of an electronic apparatus of the present invention; and

FIG. 10 is a schematic, cross-sectional view of a second embodiment of a casing of an electronic apparatus of the present invention.

### DETAILED DESCRIPTION OF THE EMBODIMENTS

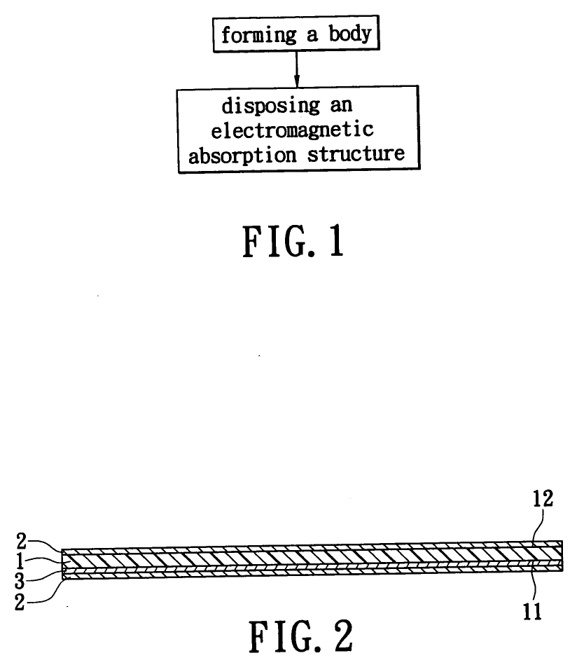

FIG. 1 and FIG. 2 illustrate a first embodiment of the present invention. The present invention provides a casing of an electronic apparatus and a manufacturing method for the same. The casing of an electronic apparatus comprises a body 1 and an electromagnetic absorption structure 2. The electromagnetic absorption structure 2 is combined with a surface of the body 1.

The manufacturing method for the casing of an electronic apparatus comprises:
(a) Forming a body 1. The body 1 may be made of plastic material. A decorative layer 3, including characters or patterns, for example, may be disposed on a surface of the body 1. In this embodiment, the body 1 has a first surface 11 and a second surface 12. The decorative layer 3 is disposed on the first surface 11. If the first surface 11 is an inner surface of the body 1, the body 1 may be made of transparent material or translucent material, so that the decorative layer 3 can be seen from the second surface 12 of the body 1 (i.e. an outer surface of the body.)
(b) Disposing an electromagnetic absorption structure 2 on a surface of the body 1 to obtain a casing of an electronic apparatus.

The electromagnetic absorption structure 2 may be a tape that absorbs electromagnetic waves. The tape is disposed on the surface of the body 1 by adhesion.

The electromagnetic absorption structure 2 may also be an electromagnetic absorption layer. The electromagnetic absorption layer is disposed on the surface of the body 1 by spraying, conventional plating, vacuum plating, vacuum sputtering, or electroless plating.

In this embodiment, the electromagnetic absorption structure 2 is disposed on both the first surface 11 and the second surface 12 of the body 1; however, it can be disposed on either the first surface 11 or the second surface 12.

The electromagnetic absorption structure 2 of the casing of an electronic apparatus absorbs electromagnetic waves. When the casing absorbs the electromagnetic waves to a saturation point, the electromagnetic waves are transformed into heat energy to dissipate and vanish. Therefore, the electromagnetic absorption structure 2 is able to eliminate the existence of the electromagnetic waves, so as to lessen the electromagnetic interference and health concerns.

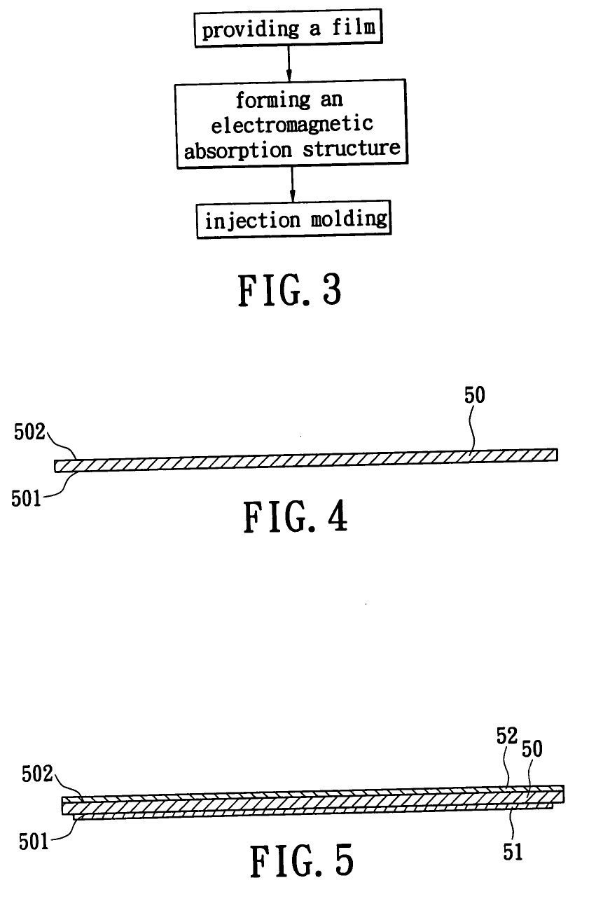

FIG. 3 to FIG. 10 illustrate a second embodiment of the present invention. The present invention provides a casing of an electronic apparatus and a manufacturing method for the same. The casing of an electronic apparatus comprises a body 4 and an electromagnetic absorption structure 5. The electromagnetic absorption structure 5 is combined with a surface of the body 4.

The manufacturing method for the casing of an electronic apparatus comprises:
(a) Providing a film, such as a plastic film made of PC: referring to FIG. 4, the film 50 has a first surface 501 and a second surface 502.

(b) Forming an electromagnetic absorption structure: referring to FIG. 5, an electromagnetic absorption layer 52 is disposed on a surface of the film 50 to form an electromagnetic absorption structure 5.

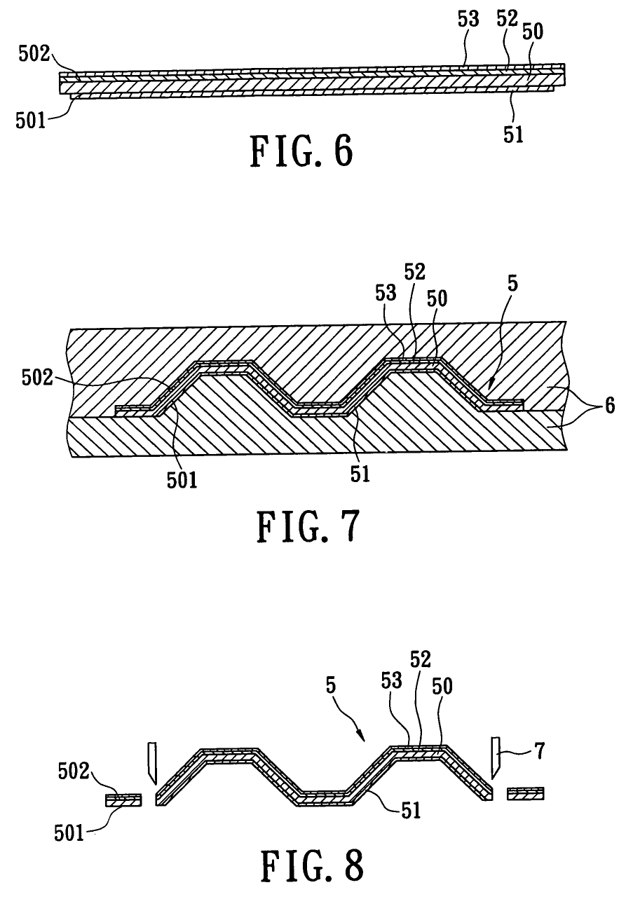

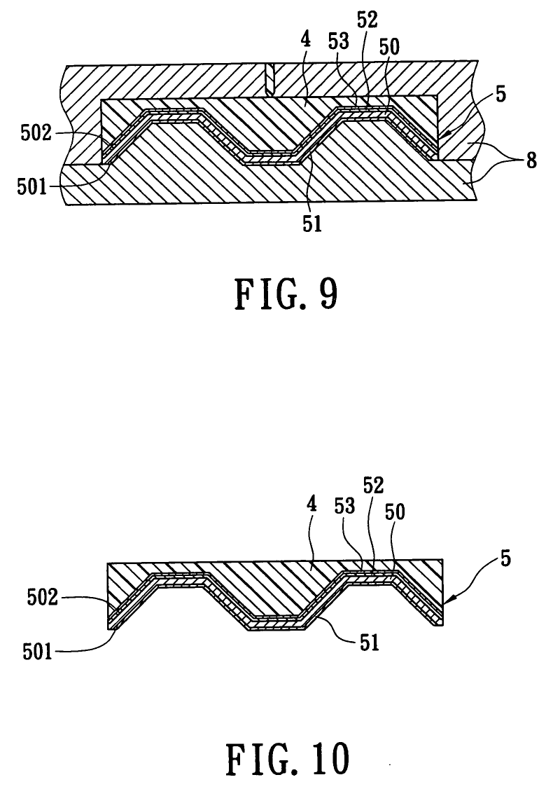

As shown in FIG. 5, in this embodiment, a decorative layer 51 is disposed on the first surface 501 of the film 50 first, and then the electromagnetic absorption layer 52 is disposed on the second surface 502 of the film 50 by spraying, conventional plating, vacuum plating, vacuum sputtering, or electroless plating. Referring to FIG. 6, the manufacturing method further comprises attaching an attachment layer 53 on the electromagnetic absorption layer 52, so as to improve the combination reliability between the electromagnetic absorption structure 5 and a body 4 (as shown in FIG. 9 and FIG. 10) formed from injection material in a subsequent step.

Referring to FIG. 7, after forming the electromagnetic absorption structure 5, the manufacturing method further comprises compressing the electromagnetic absorption structure 5. A further set of pressing and shaping molds 6 is provided, the electromagnetic absorption structure 5 is placed into the set of pressing and shaping molds 6, and the electromagnetic absorption structure 5 is compressed to form it into a three-dimensional shape, such as, for example, a shape of a keypad of a cellular phone.

Referring to FIG. 8, after forming the electromagnetic absorption structure 5, the manufacturing method further comprises punching and shearing the electromagnetic absorption structure 5; that is, further providing a punching and shearing machine 7. The punching and shearing machine 7 punches and shears the electromagnetic absorption structure 5 to obtain a predetermined specification thereof, such as a proper outline and some assembling holes, so as to provide for later assembly steps.

(c) Injection molding: providing a set of injection molding molds 8 and injection material, placing the electromagnetic absorption structure 5 into the set of injection molding molds 8, injecting the injection material into the set of injection molding molds 8 to form a body 4 combined with the electromagnetic absorption structure 5 to obtain a casing of an electronic apparatus.

Therefore, in this embodiment, the electromagnetic absorption structure 5 includes a film 50, an electromagnetic absorption layer 52, and an attachment layer 53. The film 50 has a first surface 501 and a second surface 502. A decorative layer 51 is disposed on the first surface 501 of the film 50. The electromagnetic absorption layer 52 has a surface combined with the second surface 502 of the film 50. The body 4 is combined with another surface of the electromagnetic absorption layer 52. The attachment layer 53 is disposed between the electromagnetic absorption layer 52 and the body 4. If the body 4 is outside of the casing of an electronic apparatus, the film 50 may be made of transparent material or translucent material, and the body 4 may be made of transparent material or translucent material, so that the decorative layer 51 can be seen from outside of the casing. Indeed, the decorative layer 51 may also be disposed on the second surface 502 of the film 50, and the electromagnetic absorption layer 52 may combine with the second surface 502 of the film 50.

In this embodiment, the film 50 is placed into the set of injection molding molds 8 and an insert-molding technology is applied, so that the electromagnetic absorption structure 5 completely covers the body 4. Therefore, the casing fully absorbs electromagnetic waves. Moreover, the electromagnetic absorption layer 52 is between the film 50 and the body 4, so that it will not wear or fall off and the structure for absorbing electromagnetic waves is more durable. In addition, the decorative layer 51 and the electromagnetic absorption layer 52 both combine with the film 50 first, and then the body 4 is combined with the electromagnetic absorption layer 52, so that the casing can simply have both a decorative outlook and an effect of eliminating electromagnetic waves.

As indicated above, the casing of an electronic apparatus and manufacturing method for the same of the present invention has the following advantages:
(1) The electromagnetic absorption structure is combined with the surface of the body to obtain a casing of an electronic apparatus, such that the casing is able to absorb electromagnetic waves, and the electromagnetic waves are transformed into heat energy to dissipate and vanish, thereby eliminating the existence of the electromagnetic waves, so as to lessen the electromagnetic interference and health concerns.

(2) The electromagnetic absorption layer is disposed on the film first to form an electromagnetic absorption structure, and then the film is placed into the set of injection molding molds and an insert-molding technology is applied, so that the electromagnetic absorption structure completely covers the body to obtain a casing of an electronic apparatus. Therefore, the casing fully absorbs electromagnetic waves. Moreover, the electromagnetic absorption layer is between the film and the body, so that it will not wear or fall off and the structure for absorbing electromagnetic waves is more durable.

(3) The decorative layer and the electromagnetic absorption layer both combine with the film first, and then the film is placed in the set of injection molding molds and an insert-molding technology is applied to combine the body with the electromagnetic absorption layer to obtain a casing of an electronic apparatus, so that the casing can simply have both a decorative outlook and an effect of eliminating electromagnetic waves.

It should be apparent to those skilled in the art that the above description is only illustrative of specific embodiments and examples of the invention. The invention should therefore cover various modifications and variations made to the herein-described structure and operations of the invention, provided they fall within the scope of the invention as defined in the following appended claims.

1. A casing of an electronic apparatus, comprising:
a body; and
an electromagnetic absorption structure combined with a surface of the body, wherein the electromagnetic absorption structure includes a film and an electromagnetic absorption layer, wherein the film has a first surface and a second surface and the electromagnetic absorption layer has a surface combined with the second surface of the film and the body combined with another surface of the electromagnetic absorption layer.

2. The casing of an electronic apparatus as claimed in claim 1, wherein the electromagnetic absorption structure is a tape for absorbing electromagnetic waves.

3. The casing of an electronic apparatus as claimed in claim 1, wherein the electromagnetic absorption structure is an electromagnetic absorption layer.

4. The casing of an electronic apparatus as claimed in claim 1, wherein the electromagnetic absorption structure includes a film and an electromagnetic absorption layer, the electromagnetic absorption layer having a surface combined with a surface of the film and the body being combined with another surface of the electromagnetic absorption layer.

5. The casing of an electronic apparatus as claimed in claim 1, wherein the film is made of transparent material or translucent material, a decorative layer is disposed on the first surface of the film, and the body is made of transparent material or translucent material.

6. The casing of an electronic apparatus as claimed in claim 1, wherein the electromagnetic absorption structure includes an attachment layer disposed between the electromagnetic absorption layer and the body.

7. The casing of an electronic apparatus as claimed in claim 1, wherein the electromagnetic absorption structure is formed into a three-dimensional shape.
